(19) United States
(12) Patent Application Publication
(10) Pub. No.: US 2001/0018890 A1
(43) Pub. Date: Sep. 6, 2001

(54) Method of highly purifying Si surface and a atomically flattening method for an Si surface

(76) Inventors: Shinichi Higai, Ibaraki (JP); Takahisa Oono, Ibaraki (JP)

Correspondence Address: WENDEROTH, LIND & PONACK, L.L.P., 2033 K STREET N. W., SUITE 800, WASHINGTON, DC, 20006-1021, US

(21) Appl. No.: 09/791,647

(22) Filed: Feb. 26, 2001

(30) Foreign Application Priority Data
Feb. 25, 2000 (JP) 2000-050265

(51) Int. Cl. C30B 19/00; C30B 1/00

(52) U.S. Cl. 117/54

(57) ABSTRACT

Metal impurities, particularly, Ni as a transition metal under the Si surface which are mainly attributable to surface defects are removed to highly purify the Si surface, and the Si surface is atomically flattened correspondingly by hydrogenating the Si surface containing metal impurities under the surface by means of a gas phase process or a liquid phase process, thereby extracting the metal impurities onto the Si surface.

### FIELD OF THE INVENTION

This invention concerns a method of highly purifying an Si surface and a atomically flattening method for the Si surface. More specifically, it relates to a method of highly purifying an Si surface by removing metal impurities present under the Si surface which could not be removed by existent treatment such as annealing, as well as a method of atomically flattening an Si surface by reducing the surface defects.

### PRIOR ART

Along with increasing degree of integration and fine processing in semiconductor LSI, there has been a significant problem of reducing micro roughness on the surface of an Si substrate as a main substrate material and flattening the same at the level of atom.

As a method of attaining flatness for the Si surface at the level of atom, a heating method in super-high vacuum has been known long since but the method involves problems that not only the cost is expensive but also it is difficult to maintain the flatness thereof during device manufacturing steps since the obtained surface is easily oxidized, as well as heating under high vacuum gives undesired effects on device characteristics, and this can not be said to be a practical method in view of an industrial level.

On the other hand, the surface of Si plane orientation (001) is expected to realize a highest flatness in Si. However, in the flattening for the surface of the Si plane orientation (001), presence of surface defects called as Dimer Vacancy (hereinafter referred to as DV defect) of Si gives a significant problem. The principal cause for the occurrence of the DV defect is considered to be attributable to the presence of metal impurities, particularly, Ni as a transition metal under the Si surface near the defect and, accordingly, it has been expected that the Si surface can be flattened at the level of atom by removing the metal impurities.

A contamination of Si surface caused by the metal impurities occurs as various states in processes for manufacturing Si wafer or Si-LSI.

The contamination of Si surface has an injurious influence upon characteristics of device and then decrease a reliance thereof. By removing the metal inpurities, it is expected that a stability and a reliance of device's characteristics are increased.

### SUMMARY OF THE INVENTION

This invention has been accomplished in view of the foregoing situations and it is an object thereof to provide a method of highly purifying an Si surface by removing metal impurities under the Si surface which are attributable to surface defects including the DV defects, particularly, Ni as the transition metal, as well as a method of flattening the Si surface correspondingly.

The foregoing object can be solved in accordance with this invention. This invention, at first, provides a method of highly purifying Si surface by hydrogenating an Si surface containing metal impurities under the surface as a gas phase method or liquid phase method thereby extracting the metal impurities onto the Si surface and removing the metal impurities.

Further, this invention also provides a method of atomically flattening Si surface by hydrogenating an Si surface containing metal impurities under the surface as a gas phase method or liquid phase method thereby extracting the metal impurities onto the Si surface and removing the metal impurities.

Further, this invention provides a preferred embodiment in which metal impurities are transition metals.

This invention provides another preferred embodiment in which Si surface has plane orientation (001).

This invention also provides a method of manufacturing Si wafer or Si-LSI in which the method of highly purifying the Si surface and a method of flattening the Si surface is incorporated as a portion of the process.

Furthermore, this invention provides a method of highly purifying or flattering C(carbon), Ge, Su or Pb surface by hydrogenating a surface thereof containing metal impurities under the surface as a gas phase method or liquid phase method thereby extracting the metal impurities onto the surface and removing the metal impurities.

### BRIEF DESCRIPTION OF THE INVENTION

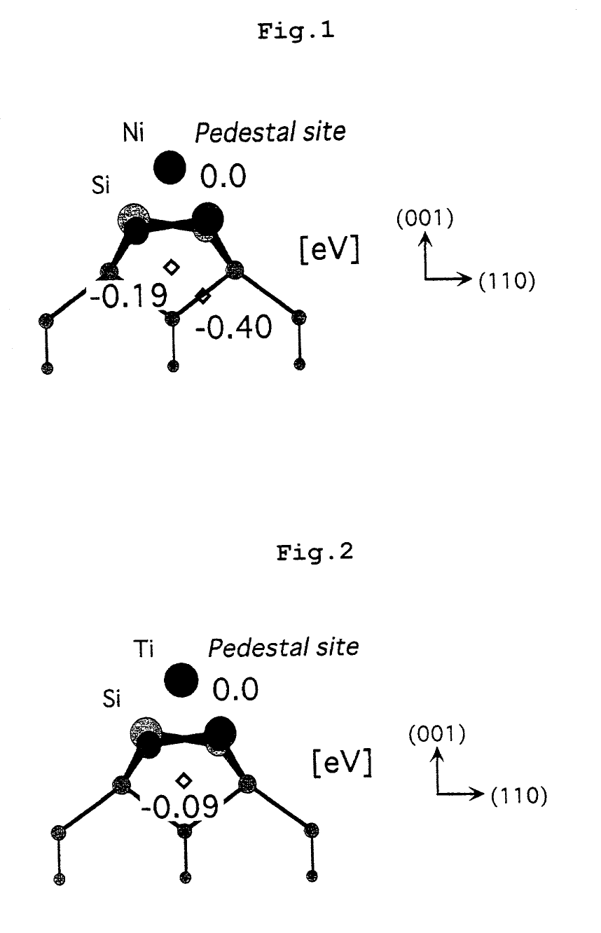

FIG. 1 shows a view illustrating an energy difference (eV) between a most stable site on an Si (001) surface and stable site inside Si of Ni atom;

FIG. 2 shows a view illustrating an energy difference between a most stable site on an Si (001) surface and stable site inside Si of Ti atom;

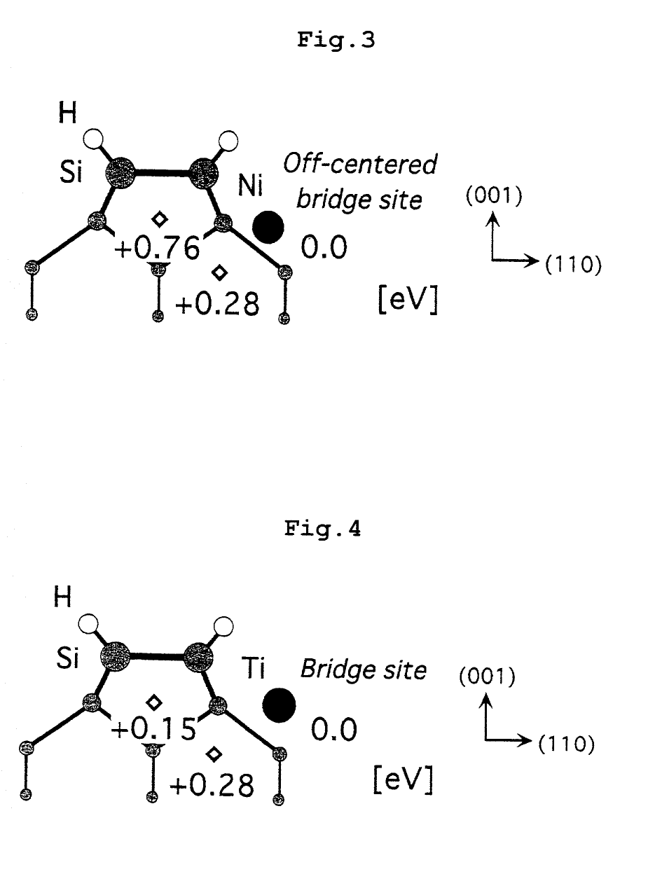

FIG. 3 shows a view illustrating an energy difference between the most stable site on the hydrogenated Si (001)−(2×1) surface and a stable site inside Si of an Ni atom;

FIG. 4 shows a view illustrating an energy difference between the most stable site on the hydrogenated Si (001)−(2×1) surface and a stable site inside Si of a Ti atom;

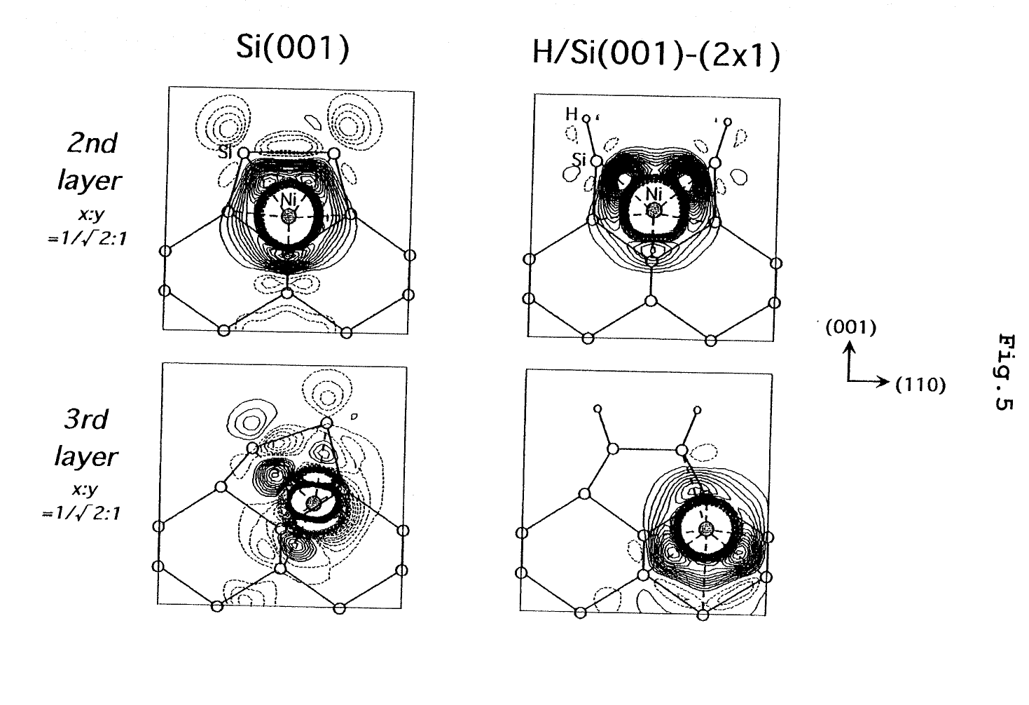

FIG. 5 shows a view illustrating a difference charge density on a clean Si (001) surface when an Ni atom is in a stable site of second and third Si layers (on the left of the figure) and a difference charge density on a hydrogenated Si (001)−(2×1) surface. The solid line represents an increased region and a broken line represents a decreased region of charge density respectively.

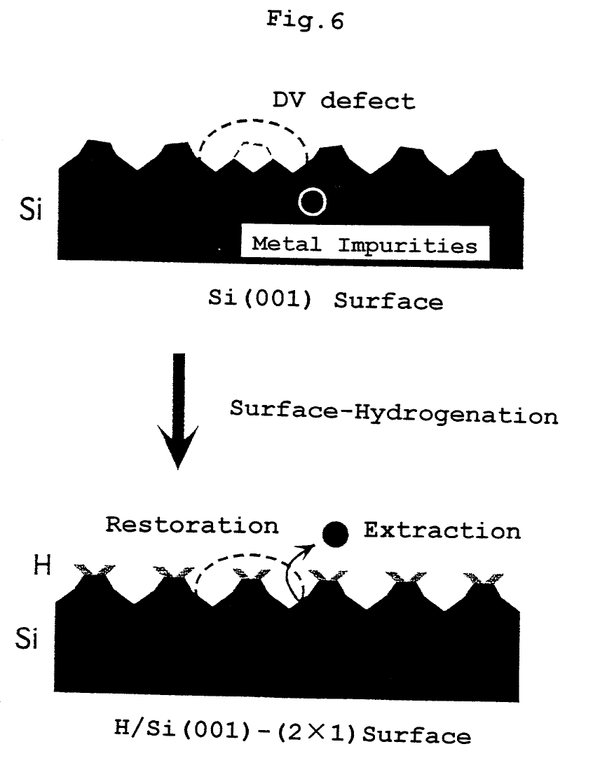

FIG. 6 shows a conceptional view illustrating a function and effect of the present invention.

### DETAILED DESCRIPTION OF THE INVENTION

This invention has features as described above and preferred embodiments thereof are to be explained below.

In this invention, when an Si surface containing metal impurities under the surface is hydrogenated, metal impurities are extracted onto the Si surface, and the Si surface is highly purified by removing the metal impurities. Further, since the metal impurities are removed, the surface defects are highly purified and the Si surface is reduced to attain atomically flatness for the Si surface.

FIG. 6 shows a conceptional view illustrating a functional and effect of the present invention, as a case of hydrogenating Si (001) surface and removing metal impurities extracted onto the surface. As a H/Si (001)−(2×1) surface. DV defect of the Si (001) surface is restorated.

Thereby Si surface is highly purified and is atomically flattened.

In this invention, hydrogenation for Si surface is conducted by the generally used gas phase method or liquid phase method. For attaining an Si surface of high flatness, use of the gas phase method is preferred since this gives less damages to the Si surface.

Metal impurities contained in Si can be removed irrespective of their kinds from Si according to this invention. Particularly, when the metal impurities are transition metals including Ni or Ti, remarkable reduction of the surface defects are obtained and the Si surface is highly flattened.

Further, Si may be of any plane orientation in this invention but high flattening for the Si surface is attained when Si has plane orientation (001) according to this invention.

Further, the method of highly purifying the Si surface or the method of atomically flattening the Si surface according to this invention can be introduced into a desired process in the manufacture of Si wafer or Si-LSI.

Extracted metal impurities onto the Si surface are removed by some kinds of method, such as gettering method.

Extraction of the metal impurities onto the Si surface by hydrogenating Si surface is occurred, as described in detail in preferred embodiments, through dangling orbit of surface Si atoms are passivated by hydrogen atoms.

In case of C (carbon), Ge, Sn and Pb, as IV group element of the periodic law, their surface-structure are similar to the Si surface having dangling orbit. Then, significant effect similar to Si surface case is realized.

This invention having the foregoing features is to be further explained specifically with reference to the knowledge on which this invention has been made.

This invention is based on a result of the first-principles theoretically calculations. The first-principles calculations are based on the density functional formalism with the generalized gradient approximation. Most significant feature is that the calculations do not use empirical parameters. For the atomic potential, pseudo-potential is adopted. The plane wave function is also adopted as the basis function. The plane wave basis set up to the cut-off energy of 20.25 Ry. The partial core correction is employed for Ni and Ti.

On this calculation, as each of lattice constant of Si, Ni and Ti is +0.5%, +1.2% and +1.3%, and each of bulk modulus of Si, Ni and Ti is −5.6%, +1.3% and +6.7%, high precision on them is reappeared. On the Si−H, bonding length of SiH₄ molecule, precision of +0.3% is obtained.

### EMBODIMENT OF THE INVENTION

FIG. 1 and FIG. 2 show an energy difference between a most stable site on a clean Si (001) surface and a stable side inside the Si of a Ti atom and Ni atom. For any of Ni atom and Ti atom, the most stable site on the Si surface is a pedestal site on the dimer row, whereas the stable site inside Si is a is more stable compared with pedestal site.

Then, FIG. 3 and FIG. 4 show an energy difference between the most stable site on the hydrogenated Si (001)−(2×1) surface and a stable site inside Si of Ni atom and Ti atom, respectively. By the hydrogenation of the Si (001) surface, the most stable site on the surface moves from the pedestal site into an off-centered bridge site between dimer rows for the Ni atom, and into a bridge site for the Ti atom. Further, the stable site inside Si which was more stable than the most stable site on the surface for a clean Si (001) surface becomes instable in any of the cases for the Ni atom and the Ti atom.

The mechanism of the phenomenon described above is shown below. FIG. 5 shows a difference charge density in which the Ni atom is on the stable site of second and third Si layers, which shows a value obtained by subtracting the difference charge density for the lone Ni atom and underlying portion from the total charge density ([total charge density]−[charge density of lone Ni atom]−[difference charge density of underlying charge density]). That is, FIG. 5 shows the state of circumstance charge transfer by the presence of Ni atom inside Si. The charge density increases greatly in the Ni—Si bonding region in any of the clean Si (001) surface and the hydrogenated Si (001)−(2×1) surface. For compensating the bonding charge of Ni—Si, charge density in the dangling orbit and the Si—Si bonded portion of the dimer Si atoms is decreased on the clean Si (001) surface. On the other hand, on the hydrogenated Si (001)−(2×1) surface, since the dangling orbit is terminated with hydrogen (II), the charge density is decreased only at the Si—Si bond portion. That is, it is considered that the absence or presence of dangling orbit reflects the stability of the Ni atom inside Si.

With the mechanisms explained above, it is possible to extract the transition metal impurities contained inside Si onto the surface by hydrogenating for Si surface. Actually, Ni can be extracted onto the Si surface by hydrogenating the Si surface by the supply of a hydrogen gas or hydrogen radicals to the Si surface, thereby highly purifying and atomically flattening the Si surface.

In the foregoing explanations, Ni and Ti are mentioned as examples of metal impurities, but it would be apparent that other transition metals, as well as all sorts of metal impurities can be removed by this invention.

Further, while Si surface having plane orientation (001) is shown as an example in the foregoing explanation. However, since presence of the dangling orbit on the surface is attributable to the stable presence of metal impurities inside Si as described above, and the dangling orbit always remains on the clean Si surface although various reconstitutions are observed for elimination of unstable dangling orbit, so that metal impurities inside Si can be removed by this invention also for other plane orientation.

Furthermore, as described above, along with removal of metal impurities contained inside Si, since the surface defects are decreased, atomically flattening for the Si surface can be attained.

The method of hydrogen-annealing is generally known as an effective method for solving problems on pollution or contamination of metal impurities on the surface of Si wafer. However, this known method is essentially different from the method of present invention as follows;

1) Hydrogen atom is eliminated from the hydrogenated Si surface at the temperature of from about 400° C. to 600° C. The hydrogen-annealing method as known method is carried at the high temperature of from about 900° C. to 1200° C. Then, in this known method, hydrogen atom can not cause termination of Si dangling orbit.

2) The method of present invention aims at attracting surface defect as single atomic level. On the contrary, hydrogen-annealing of known method airms at attracting surface defect as more large scale of μm level.

As has been described above specifically, highly purification of SI surface by the removal of metal impurities contained inside Si and corresponding atomically flattening of the Si surface at the level of atom by reduction of surface defects on the Si surface can be obtained in accordance with this invention. Time and cost for manufacturing highly pure and flat Si surfaces can be saved remarkably and, further, when the method according to this invention is introduced into the manufacturing process for Si wafer or Si-LSI, finer fabrication can be applied and it is expected that the invention contributes to the manufacture of LSI at a reduced cost.

What is claimed is:

1. A method of highly purifying Si surface by hydrogenating the Si surface containing metal impurities under the surface as a gas phase method or liquid phase method thereby extracting the metal impurities onto the Si surface and removing the metal impurities.

2. A method of atomically flattening Si surface by hydrogenating the Si surface containing metal impurities under the surface as a gas phase method or liquid phase method thereby extracting the metal impurities onto the Si surface and removing the metal impurities.

3. A method of highly purifying Si surface as defined in claim 1, wherein the metal impurities are transition metals.

4. A method of highly purifying Si surface as defined in claim 1 or 3, wherein Si surface has plane orientation (001).

5. A method of atomically flattening Si surface as defined in claim 2, wherein the metal impurities are transition metals.

6. A method of atomically flattening Si surface as defined in claim 2 or 5, wherein Si surface has plane orientation (001).

7. A method of manufacturing Si wafer or Si-LSI in which a method in any of claims 1 to 6 is incorporated as a portion of a process.

8. A method of highly purifying surface of C, Ge, Sn or Pb by hydrogenating the surface containing metal impurities under the surface as a gas phase method or liquid phase method thereby extracting the metal impurities onto the surface and removing the metal impurities.

9. A method of atomically flattening surface of C, Ge, Sn or Pb by hydrogenating the surface containing metal impurities under the surface as a gas phase method or liquid phase method thereby extracting the metal impurities onto the surface and removing the metal impurities.
